(19) United States
(12) Patent Application Publication
(10) Pub. No.: US 2026/0013107 A1
(43) Pub. Date: Jan. 8, 2026

(54) CAPACITOR, METHOD OF MANUFACTURING CAPACITOR, ELECTRONIC DEVICE INCLUDING CAPACITOR, AND METHOD OF MANUFACTURING ELECTRONIC DEVICE

(71) Applicant: Seoul National University R&DB foundation, Seoul (KR)

(72) Inventors: Cheol Seong Hwang, Seoul (KR); Haewon Song, Seoul (KR)

(21) Appl. No.: 19/255,918

(22) Filed: Jun. 30, 2025

(30) Foreign Application Priority Data
Jul. 2, 2024 (KR) 10-2024-0087144

(51) Int. Cl. H10B 12/00; H01G 4/10; H01G 4/30

(52) U.S. Cl. CPC H10B 12/315; H01G 4/10; H01G 4/306; H10B 12/033

(57) ABSTRACT

The present disclosure provides a method of manufacturing a capacitor including a first electrode, a second electrode disposed spaced apart from the first electrode, and a dielectric layer disposed between the first electrode and the second electrode, wherein the dielectric layer may include a doped layer region doped with magnesium (Mg), and the dielectric layer may have a non-uniform magnesium (Mg) doping concentration profile along a thickness direction of the dielectric layer between the first electrode and the second electrode.

### CROSS-REFERENCE TO RELATED APPLICATION

This application claims priority of Korean Patent Application No. 10-2024-0087144, filed on Jul. 2, 2024, in the KIPO (Korean Intellectual Property Office), the disclosure of which is incorporated herein entirely by reference.

### BACKGROUND OF THE INVENTION

### Field of the Invention

The present invention relates to electrical elements, devices comprising them, and methods of manufacturing them, and more particularly to capacitors, methods of manufacturing capacitors, electronic devices comprising capacitors, and methods of manufacturing electronic devices.

### Description of the Related Art

Advances in semiconductor manufacturing process technology are accelerating the scale reduction of integrated circuits. In the case of dynamic random access memory (DRAM), a typical semiconductor device, the area occupied by the capacitor, the basic element of the memory cell, is gradually decreasing. However, despite the reduced area, it is necessary to secure a certain level of capacitance for the capacitor in consideration of performance, lifetime, error margin, etc. during device operation. In this regard, the development of high-k materials (i.e., high-k materials) and continuous performance improvement related to capacitors are required to maintain the capacitance of capacitors.

Among high permittivity materials, TiO₂, for example, has the advantage of having a theoretically high permittivity of about 100 or more in the rutile crystal phase. However, high conductivity materials such as TiO₂ have the disadvantage that they have relatively large leakage currents, which limits and makes it difficult to achieve a thin equivalent oxide thickness (EOT). As a result, materials with relatively high dielectric constants, such as TiO₂, may be used instead, such as zirconium oxide, hafnium oxide, and aluminum oxide, which have smaller dielectric constants than TiO₂ but better leakage current characteristics. Therefore, in order to make high conductivity materials useful in practice, it is necessary to improve the leakage current characteristics of high conductivity materials.

### SUMMARY OF THE INVENTION

The technical challenge of the present invention is to provide a capacitor comprising a dielectric layer and a method of fabrication thereof that has a high dielectric constant but can achieve a thin equivalent oxide film thickness (EOT) with improved leakage current characteristics.

Furthermore, the technical challenge of the present invention is to provide an electronic device (e.g., a memory device) comprising the aforementioned capacitor and a method for manufacturing the same.

The problems that the present invention is intended to solve are not limited to those mentioned above, and other problems not mentioned will be understood by those skilled in the art from the following description.

According to one embodiment of the present invention, there is provided a capacitor comprising a first electrode; a second electrode spaced apart from the first electrode; and a dielectric layer disposed between the first electrode and the second electrode, the dielectric layer comprising a doped layer region doped with magnesium (Mg), the dielectric layer having a non-uniform magnesium (Mg) doping concentration profile along a thickness direction of the dielectric layer between the first electrode and the second electrode.

The dielectric layer may comprise a first doped layer region doped with magnesium (Mg), which is in contact with or adjacent to the first electrode; and a second doped layer region doped with magnesium (Mg), spaced apart from the first doped layer region and which is in contact with or adjacent to the second electrode.

The dielectric layer may comprise an intermediate doping layer region doped with magnesium (Mg) between the first and second doping layer regions. The magnesium (Mg) doping concentration of the intermediate doping layer region may be lower than the magnesium (Mg) doping concentration of each of the first and second doping layer regions.

The dielectric layer may comprise an undoped region between the first and second doped layer regions.

The dielectric layer may comprise at least one of selected from the group consisting of: titanium oxide, silicon oxide, silicon nitride, aluminum oxide, tantalum oxide, strontium titanium oxide, zirconium oxide, hafnium oxide, hafnium silicon oxide, lanthanum oxide, yttrium oxide, and lanthanum aluminum oxide.

The dielectric layer may comprise titanium oxide.

The dielectric layer may have a rutile crystalline phase.

The first electrode may comprise at least one of selected from the group consisting of: ruthenium, ruthenium oxide, iridium, iridium oxide, molybdenum, molybdenum oxide, tin, and tin oxide.

The second electrode may comprise at least one of selected from the group consisting of: ruthenium, ruthenium oxide, iridium, iridium oxide, molybdenum, molybdenum oxide, tin, and tin oxide.

According to another embodiment of the present invention, there is provided a memory element comprising the aforementioned capacitor as a data storage member.

The memory device may comprise a dynamic random access memory (DRAM).

According to another embodiment of the present invention, there is provided a method of fabricating a capacitor, comprising the steps of preparing a first electrode; forming a dielectric layer on the first electrode using an atomic layer deposition (ALD) process; and forming a second electrode on the dielectric layer, wherein the dielectric layer comprises a doped layer region doped with magnesium (Mg), the dielectric layer having a non-uniform magnesium (Mg) doping concentration profile along a thickness direction of the dielectric layer between the first electrode and the second electrode.

The dielectric layer may comprise: a first doped layer region doped with magnesium (Mg), which is in contact with to or adjacent to the first electrode; and a second doped layer region doped with magnesium (Mg), spaced apart from the first doped layer region and which is in contact with or adjacent to the second electrode.

The dielectric layer may comprise an intermediate doping layer region doped with magnesium (Mg) between the first and second doping layer regions. The magnesium (Mg) doping concentration of the intermediate doping layer region may be lower than the magnesium (Mg) doping concentration of each of the first and second doping layer regions.

The dielectric layer may comprise an undoped region between the first and second doped layer regions.

The step of forming a dielectric layer, the step of forming a first dielectric layer on the first electrode using an ALD process; performing a first magnesium (Mg) doping process on the first dielectric layer using an ALD process; forming a second dielectric layer on the first dielectric layer on which the first magnesium (Mg) doping process has been performed using an ALD process; and forming a second dielectric layer on the second dielectric layer on which the second magnesium (Mg) doping process has been performed using an ALD process; performing a second magnesium (Mg) doping process on the second dielectric layer using an ALD process; and forming a third dielectric layer on the second dielectric layer in which the second magnesium (Mg) doping process was performed using an ALD process.

The step of forming the first dielectric layer may comprise: supplying a precursor for a formation of the dielectric layer within a chamber in which the first electrode is disposed; purging the chamber with a first purge gas; supplying a first reactant within the chamber; and purging the chamber with a second purge gas.

The step of performing the first magnesium (Mg) doping process may comprise: supplying a precursor of Mg in the chamber; purging the chamber with a third purge gas; supplying a second reactant in the chamber; and purging the chamber with a fourth purge gas.

The dielectric layer may comprise at least one of selected from the group consisting of: titanium oxide, silicon oxide, silicon nitride, aluminum oxide, tantalum oxide, strontium titanium oxide, zirconium oxide, hafnium oxide, hafnium silicon oxide, lanthanum oxide, yttrium oxide, and lanthanum aluminum oxide.

The dielectric layer may comprise titanium oxide.

The dielectric layer may have a rutile crystalline phase.

At least one of the first and second electrodes may comprise at least one of selected from the group consisting of: ruthenium, ruthenium oxide, iridium, iridium oxide, molybdenum, molybdenum oxide, tin, and tin oxide.

According to embodiments of the present disclosure, it is possible to implement a capacitor comprising a dielectric layer that can have a thin equivalent oxide thickness (EOT) with improved leakage current characteristics while still having a high permittivity. According to one embodiment, the dielectric layer may include doped layer regions doped with magnesium (Mg) and may have a non-uniform magnesium (Mg) doping concentration profile along the thickness direction of the dielectric layer. For example, the dielectric layer may include a first doped layer region in contact with or adjacent to a first electrode and a second doped layer region in contact with or adjacent to a second electrode. In this case, the effect of significantly improving the leakage current characteristics of the dielectric layer in both directions can be obtained. Furthermore, the leakage current blocking effect can be further improved by the characteristics of the divalent element magnesium (Mg), and as a result, a smaller equivalent oxide thickness (EOT) can be obtained.

The capacitors according to embodiments of the present invention can be usefully applied to electronic devices, for example, memory devices such as DRAM, which can advantageously improve the integration and performance of the memory devices.

However, the effects of the present invention are not limited to the above effects, and may be extended in various ways without departing from the technical ideas and scope of the present invention.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 is a cross-sectional view illustrating a capacitor according to one embodiment of the present invention.

FIG. 2 is a cross-sectional view illustrating a capacitor according to another embodiment of the present invention.

FIG. 3 is a cross-sectional view illustrating a capacitor according to another embodiment of the present invention.

FIGS. 4A through 4G are cross-sectional views illustrating a method of fabricating a capacitor according to one embodiment of the present invention.

FIG. 5 is a graph illustrating a sequence of ALD processes for dielectric layer formation that can be applied to a method of manufacturing a capacitor according to one embodiment of the present invention.

FIGS. 6A through 6F are cross-sectional views illustrating a method of fabricating a capacitor according to another embodiment of the present invention.

FIG. 7 is a drawing to illustrate a method for fabricating a capacitor device (sample) for obtaining experimental data.

FIG. 8 is a graph showing the results of measuring/evaluating the current leakage characteristics, dielectric constant, and equivalent oxide thickness (EOT) as a function of the position of the Mg—O cycle of the capacitor element of FIG. 7.

FIG. 9 is a graph showing the results of X-ray photoelectron spectroscopy (XPS) analysis of dielectric layers prepared in accordance with embodiments and comparative examples of the present invention.

FIG. 10 is a graph showing the results of evaluating the dielectric constant of a dielectric layer according to the embodiments and comparative examples described in FIG. 9.

FIG. 11 is a graph showing the results of evaluating the electrical characteristics of a capacitor with a dielectric layer according to the embodiments and comparative examples described in FIG. 9.

FIG. 12 is a graph showing a magnesium (Mg) doping concentration profile in a dielectric layer as measured by time-of-flight secondary ion mass spectrometry (ToF-SIMS) that can be obtained in a method of manufacturing a capacitor according to one embodiment of the present invention.

FIG. 13 is a diagram illustrating an exemplary configuration of a DRAM device to which a capacitor may be applied according to one embodiment of the present invention.

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. In addition, a term such as a “unit”, a “module”, a “block” or like, when used in the specification, represents a unit that processes at least one function or operation, and the unit or the like may be implemented by hardware or software or a combination of hardware and software.

Reference herein to a layer formed “on” a substrate or other layer refers to a layer formed directly on top of the substrate or other layer or to an intermediate layer or intermediate layers formed on the substrate or other layer. It will also be understood by those skilled in the art that structures or shapes that are “adjacent” to other structures or shapes may have portions that overlap or are disposed below the adjacent features.

In this specification, the relative terms, such as “below”, “above”, “upper”, “lower”, “horizontal”, and “vertical”, may be used to describe the relationship of one component, layer, or region to another component, layer, or region, as shown in the accompanying drawings. It is to be understood that these terms are intended to encompass not only the directions indicated in the figures, but also the other directions of the elements.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

FIG. 1 is a cross-sectional view illustrating a capacitor according to one embodiment of the present invention.

Referring to FIG. 1, a capacitor according to an embodiment of the present invention may include a first electrode E10, a second electrode E20 disposed spaced apart from the first electrode E10, and a dielectric layer D10 disposed between the first electrode E10 and the second electrode E20. One side of the dielectric layer D10 may be in contact with the first electrode E10, and the other side of the dielectric layer D10 may be in contact with the second electrode E20. In one embodiment, the first electrode E10 may be a lower electrode and the second electrode E20 may be a higher electrode.

According to an embodiment of the present invention, the dielectric layer D10 may comprise a doped layer region doped with magnesium (Mg). Further, the dielectric layer D10 may have a non-uniform magnesium (Mg) doping concentration profile along the thickness direction of the dielectric layer D10 between the first electrode E10 and the second electrode E20. From the first electrode E10 to the second electrode E20, the magnesium (Mg) doping concentration within the dielectric layer D10 may change in a given manner.

According to one embodiment, the dielectric layer (D10) may include a first doped layer region R10 doped with magnesium (Mg) and a second doped layer region R20 doped with magnesium (Mg). The first doped layer region R10 may be disposed in contact with or adjacent to the first electro pole E10. The second doping layer region R20 may be disposed in contact with or adjacent to the second electrode E20. The second doping layer region R20 may be spaced apart from the first doping layer region R10.

The first doping layer region R10 may be in contact with the first electrode E10 or may be disposed close to the first electrode E10 at some distance from the first electrode E10. In the latter case, the spacing between the first doping layer region R10 and the first electrode E10 may be, as a non-limiting example, about 20 Å or less. In this case, the first doping layer region R10 may be disposed close to the first electrode E10 of the first and second electrodes E10 and E20. In this case, an undoped region (a region not doped with magnesium) may be disposed between the first doping layer region R10 and the first electrode E10. However, preferably, the first doping layer region R10 may be disposed in contact with the first electrode E10.

The second doping layer region R20 may be in contact with the second electrode E20 or may be disposed close to the second electrode E20 at some distance from the second electrode E20. In the latter case, the spacing between the second doping layer region R20 and the second electrode (E20) may be, as a non-limiting example, about 20 Å or less. In this case, the second doping layer region R20 may be disposed close to the second electrode E20 of the first and second electrodes E10 and E20. In this case, an undoped region (a region not doped with magnesium) may be disposed between the second doping layer region R20 and the second electrode E20. However, preferably, the second doping layer region R20 may be disposed in contact with the second electrode E20.

The dielectric layer D10 may include an intermediate doping layer region R30 doped with magnesium (Mg) between the first and second doping layer regions R10, R20. The magnesium (Mg) doping concentration of the intermediate doping layer region R30 may be lower than the magnesium (Mg) doping concentration of each of the first and second doping layer regions R10 and R20. The average magnesium (Mg) doping concentration of the intermediate doping layer region R30 may be lower than the average magnesium (Mg) doping concentration of each of the first and second doping layer regions R10 and R20. In this case, the dielectric layer D10 may have a high magnesium (Mg) doping concentration at both ends or adjacent thereto along its thickness direction.

According to one embodiment, the first doped layer region R10 may have a doping concentration profile in which the magnesium (Mg) doping concentration is highest at or adjacent to its center along the thickness direction and the magnesium (Mg) doping concentration gradually decreases toward the two ends (top and bottom in the drawings) along the thickness direction. Similarly, the second doping layer region R20 may have a doping concentration profile in which the magnesium (Mg) doping concentration is highest in a central portion along the thickness direction or a portion adjacent thereto, and the magnesium (Mg) doping concentration gradually decreases toward the two ends along the thickness direction (top and bottom in the drawings). On the other hand, the middle doped layer region R30 may have a doping concentration profile in which the magnesium (Mg) doping concentration is lowest in the center or adjacent thereto along the thickness direction and the magnesium (Mg) doping concentration gradually increases toward the two ends (top and bottom in the drawing) along the thickness direction.

The dielectric layer D10 may comprise, for example, titanium oxide (TiO₂), silicon oxide (SiO₂), silicon nitride (Si₃N₄), aluminum oxide (Al₂O₃), tantalum oxide (Ta₂O₅), strontium titanium oxide (SrTiO₃), zirconium oxide (ZrO₂), hafnium oxide (HfO₂), hafnium silicon oxide (HfSiO₄), lanthanum oxide (La₂O₃), yttrium oxide (Y₂O₃), and lanthanum aluminum oxide (LaAlO₃). The dielectric layer (D10) may comprise at least one of titanium oxide (TiO₂), silicon oxide (SiO₂), silicon nitride (Si₃N₄), aluminum oxide (Al₂O₃), tantalum oxide (Ta₂O₅), strontium titanium oxide (SrTiO₃), zirconium oxide (ZrO₂), and hafnium oxide (HfO₂), hafnium silicon oxide (HfSiO₄), lanthanum oxide (La₂O₃), yttrium oxide (Y₂O₃), and lanthanum aluminum oxide (LaAlO₃), and may include a doped layer region doped with magnesium (Mg) formed from any one of these materials. Preferably, the dielectric layer D10 may be, but is not limited to, a high permittivity material layer. The material of the dielectric layer D10 may be an oxide, but may not be an oxide.

In one example, the dielectric layer D10 may comprise titanium oxide (TiO₂) or may comprise a doped layer region formed from titanium oxide (TiO₂) and doped with magnesium (Mg). In this case, the dielectric layer D10 may have a rutile crystalline phase, i.e., a rutile crystal structure. The titanium oxide (TiO₂) contained in the dielectric layer D10 may have a rutile crystalline phase. When the dielectric layer D10 includes titanium oxide (TiO₂) having a rutile crystalline phase, the dielectric layer D10 may have a significantly higher dielectric constant. The dielectric constant of the dielectric layer D10 may be, for example, about 80 or more or about 90 or more.

The thickness of the dielectric layer D10 may be about 5˜30 nm or about 7˜20 nm, as a non-limiting example. In the embodiment of FIG. 1, the thickness of the dielectric layer D10 may be relatively thin. When the thickness of the dielectric layer D10 is relatively thin, the dielectric layer D10 may include the first and second doping layer regions R10 and R20 and an intermediate doping layer region R30 disposed between them. In this case, the intermediate doping layer region R30 may be in contact with the first and second doping layer regions R10 and R20, respectively. Further, the dielectric layer D10 may have a structure doped with magnesium (Mg) as a whole.

According to one embodiment, the first electrode E10 may comprise at least one of ruthenium (Ru), ruthenium oxide (RuO₂), iridium (Ir), iridium oxide (IrO₂), molybdenum (Mo), molybdenum oxide (MoO₂), tin (Sn), and tin oxide (SnO₂). For example, ruthenium oxide (RuO₂) may have crystal similarities to the rutile phase of Ti₂, which has a high dielectric constant. When the ruthenium oxide RuO₂ is used as the first electrode (E10), TiO₂ having a high dielectric constant, i.e., TiO₂ having a rutile phase, can be formed on it. When ruthenium (Ru) is used as the first electrode E10, in the process of depositing TiO₂ on the Ru layer, the surface portion of the Ru layer can be oxidized to RuO₂ by an oxidizing agent, and rutile TiO₂ having a high conductivity can be deposited on the RuO₂, IrO₂, MoO₂, SnO₂, and the like may be electrode materials capable of forming rutile TiO₂ having a high dielectric constant. However, the specific material of the first electrode E10 is not limited to the foregoing.

According to one embodiment, the second electrode E20 may include a second first electrode E20a and a second electrode E20b. The second electrode E20 may be stacked (formed) on the dielectric layer D10 with the second electrode E20a and the second electrode E20b in sequence. The second first electrode E20a may include at least one of, for example, ruthenium (Ru), ruthenium oxide (RuO₂), iridium (Ir), iridium oxide (IrO₂), molybdenum (Mo), molybdenum oxide (MoO₂), tin (Sn), and tin oxide (SnO₂). For example, the material of the second first electrode E20a may be the same as the material of the first electrode E10. RuO₂, IrO₂, MoO₂, SnO₂, and the like may have a crystal similarity to rutile TiO₂ having a high dielectric constant, and may be advantageous for improving the crystallinity of the dielectric layer D10 and securing a high dielectric constant. When post metallization annealing (PMA) is performed in the manufacture of the capacitor, the material of the second first electrode E20a during the PMA process may be advantageous for improving the crystallinity of the dielectric layer D10 and securing the high dielectric constant.

The second electrode E20b may additionally be formed for purposes such as enhancing physical strength. The second electrode E20b may comprise, as a non-limiting example, at least one of platinum (Pt), copper (Cu), molybdenum (Mo), cobalt (Co), palladium (Pd), gold (Au), iridium (Ir), tungsten (W), and nickel (Ni). The second electrode (E20b) may comprise a metal or an alloy, and may have a monolayer structure or a multilayer structure (laminated structure). The formation of the second electrode E20b may be optional and may be omitted. In the absence of the second electrode E20b, the second first electrode E20a may be considered as the “second electrode”.

The capacitor according to the embodiment of FIG. 1 may be a metal-insulator-metal (MIM) capacitor. In this case, the first electrode E10 and the second electrode E20 may comprise a metal or metallic material.

According to an embodiment of the present invention, the dielectric layer D10 may include a doped layer region doped with magnesium (Mg) and may have a non-uniform magnesium (Mg) doping concentration profile along a thickness direction of the dielectric layer D10 between the first electrode E10 and the second electrode E20. The dielectric layer D10 may include a first doping layer region R10 in contact with or adjacent to the first electrode E10 and a second doping layer region R20 in contact with or adjacent to the second electrode E20. The first and second doping layer regions R10 and R20 may be regions doped with magnesium (Mg).

Since the first and second doped layer regions R10 and R20 can play the role of an excellent electron blocking layer, the dielectric layer D10 can have a high dielectric constant while having a low leakage current characteristic. The first and second doping layer regions R10 and R20 can play the role of effectively blocking/inhibiting the flow of electrons in both directions. The first doping layer region R10 may play a role in effectively blocking/inhibiting the flow of electrons from the first electrode E10 to the dielectric layer D10 when a positive voltage is applied to the capacitor. The second doping layer region R20 can effectively block/inhibit the flow of electrons from the second electrode E20 to the dielectric layer D10 when a negative voltage is applied to the capacitor. By having both the first and second doping layer regions R10 and R20, the effect of greatly improving the leakage current characteristics of the dielectric layer D10 in both directions can be obtained.

Furthermore, the leakage current blocking effect can be further improved by the divalent nature of magnesium (Mg), which results in a smaller equivalent oxide thickness (EOT). For example, the energy level created by the substitution of +4 Ti by a +2 valence dopant (i.e., Mg) can hold (i.e., capture) one additional electron compared to the energy level created by the substitution of a +3 valence dopant (i.e., Al), so the energy barrier raising effect can be more effective in the doping of +2 valence dopant materials. Therefore, the leakage current blocking effect can be further improved by doping with magnesium (Mg).

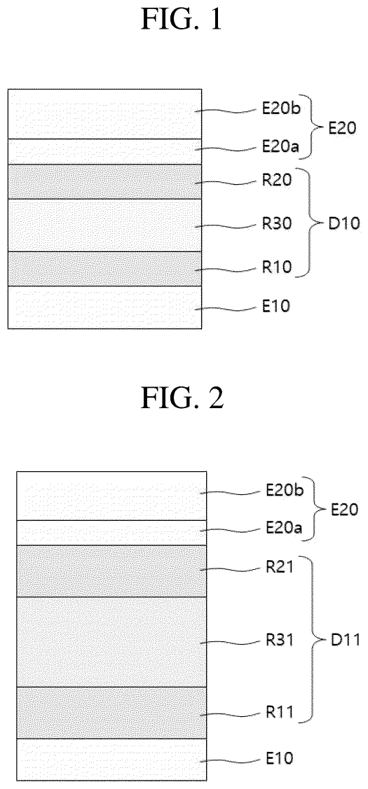

FIG. 2 is a cross-sectional view illustrating a capacitor according to another embodiment of the present invention.

Referring to FIG. 2, the capacitor according to the present embodiment may include a first electrode E10, a second electrode E20 disposed spaced apart from the first electrode E10, and a dielectric layer D11 disposed between the first electrode E10 and the second electrode E20. The dielectric layer D11 may include a doped layer region doped with magnesium (Mg). Further, the dielectric layer D11 may have a non-uniform magnesium (Mg) doping concentration profile along the thickness direction of the dielectric layer D11 between the first electrode E10 and the second electrode E20. From the first electrode E10 to the second electrode E20, the magnesium (Mg) doping concentration within the dielectric layer D11 may change in a given manner.

According to one embodiment, the dielectric layer D11 may include a first doped layer region R11 doped with magnesium (Mg) and a second doped layer region R21 doped with magnesium (Mg). The first doping layer region R11 may be disposed in contact with or adjacent to the first electrode E10. The second doping layer region R21 may be disposed in contact with or adjacent to the second electrode E20. The second doping layer region R21 may be spaced apart from the first doping layer region R11.

The first doping layer region R11 may be disposed close to the first electrode E10, either in contact with the first electrode E10 or somewhat spaced apart from the first electrode E10. Preferably, the first doping layer region R11 may be disposed in contact with the first electrode E10. The second doping layer region R21 may be disposed close to the second electrode E20, either in contact with the second electrode E20 or somewhat spaced apart from the second electrode E20. Preferably, the second doping layer region R21 may be disposed in contact with the second electrode E20.

The dielectric layer D11 may include an undoped region R31 that is not doped with magnesium (Mg) between the first and second doped layer regions R11 and R21. The undoped region R31 may be in contact with the first and second doped layer regions R11 and R21, respectively. The first doped layer region R11 may have a doping concentration profile in which the magnesium (Mg) doping concentration is highest at or adjacent to its center along the thickness direction and the magnesium (Mg) doping concentration gradually decreases toward the two ends (top and bottom in the drawing) along the thickness direction. Similarly, the second doped layer region R21 may have a doping concentration profile in which the magnesium (Mg) doping concentration is highest in the center or adjacent thereto along the thickness direction and the magnesium (Mg) doping concentration gradually decreases toward the two ends (top and bottom in the drawing) along the thickness direction.

The thickness of dielectric layer D11 may be, as a non-limiting example, about 5˜30 nm or about 7˜20 nm. In the embodiment of FIG. 2, the thickness of the dielectric layer D11 may be relatively thick. When the dielectric layer D11 has a relatively thick thickness, the dielectric layer D11 may include first and second doped layer regions R11 and R21 and an undoped region R31 disposed therebetween.

The materials and properties (crystallographic characteristics) applicable to each of the dielectric layer D11, the first electrode E10, and the second electrode E20 may be the same or similar to those described for the dielectric layer D10, the first electrode E10, and the second electrode E20 in FIG. 1.

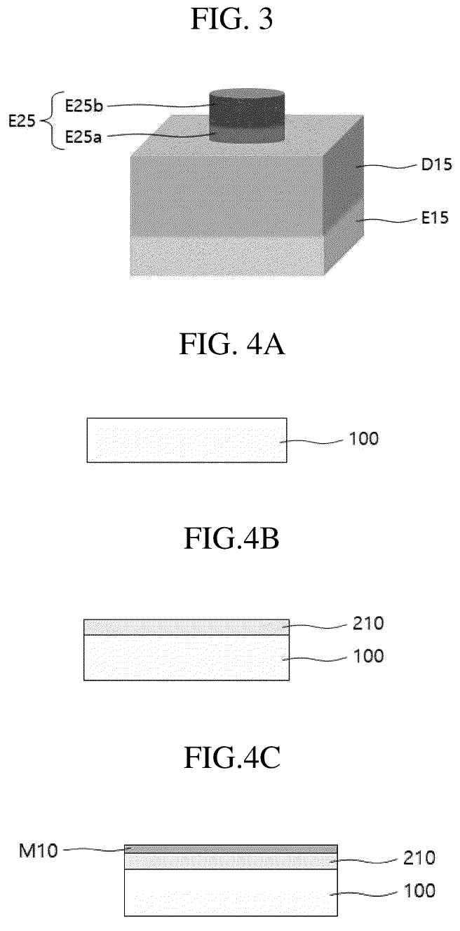

FIG. 3 is a cross-sectional view illustrating a capacitor according to another embodiment of the present invention. FIG. 3 may be a capacitor device (sample) fabricated to obtain experimental data.

Referring to FIG. 3, the capacitor may include a first electrode E15, a second electrode E25 disposed spaced apart from the first electrode E15, and a dielectric layer D15 disposed between the first electrode E15 and the second electrode E25. The dielectric layer D15 may include a doped layer region doped with magnesium (Mg). The dielectric layer D15 may have a non-uniform magnesium (Mg) doping concentration profile along a thickness direction of the dielectric layer D15 between the first electrode E15 and the second electrode E25. The dielectric layer D15 may correspond to the dielectric layer D10 of FIG. 1 or the dielectric layer D11 of FIG. 2. The second electrode E25 may include a second first electrode E25a and a second electrode E25b.

The capacitor may be fabricated in a metal-insulator-metal (MIM) structure. The capacitor may have a structure of Si wafer/thermal oxidized SiO₂ (100 nm)/sputtered Ru (50 nm)/Mg-doped TiO₂ (7˜20 nm)/sputtered RuO₂ (30 nm)/sputtered Pt (50 nm), starting with a silicon wafer as a substrate. Here, the dimensions in parentheses indicate non-limiting and exemplary thicknesses (thickness ranges).

As the first electrode E15 and the second first electrode E25a, sputter-deposited Ru (RuO₂) can be used. RuO₂ may have a crystal similarity to the rutile phase of TiO₂, which has a high dielectric constant. The Ru used as the first electrode E15 may be oxidized to RuO₂ by an oxidizing agent having a high oxidizing power (e.g., O₃) during the deposition of the TiO₂ layer above it, and high dielectric constant TiO₂ may be deposited on the RuO₂ phase. MoO₂, IrO₂, SnO₂, etc. may also play a similar role to RuO₂. Thus, the first electrode E15 may comprise at least one of ruthenium (Ru), ruthenium oxide (RuO₂), iridium (Ir), iridium oxide (IrO₂), molybdenum (Mo), molybdenum oxide (MoO₂), tin (Sn), and tin oxide (SnO₂).

The dielectric layer D15 may be a layer formed by an atomic layer deposition (ALD) process. The formation method of the dielectric layer D15 will be described in detail later. For the second first electrode E25a, as with the first electrode E15, a RuO₂ layer that has crystal similarity to the high conductivity rutile TiO₂ to help secure high conductivity properties may be used. The second electrode E25b is for enhancing physical strength, for example, a Pt layer may be used as the second electrode E25b. The second electrode E25 may have a multilayer structure (e.g., a bilayer structure). However, the use of the second electrode E25b may be optional. The second first electrode E25a may comprise at least one of, for example, ruthenium (Ru), ruthenium oxide (RuO₂), iridium (Ir), iridium oxide (IrO₂), molybdenum (Mo), molybdenum oxide (MoO₂), tin (Sn), and tin oxide (SnO₂). The second electrode E25b may comprise, for example, at least one of platinum (Pt), copper (Cu), molybdenum (Mo), cobalt (Co), palladium (Pd), gold (Au), iridium (Ir), tungsten (W), and nickel (Ni).

Although the embodiment of FIG. 3 mainly describes the application of TiO₂ as the material of the dielectric layer D15, the material of the dielectric layer D15 is not limited to TiO₂, and various other dielectric materials other than TiO₂ may be applied. Dielectric layer D15 may comprise, for example, titanium oxide (TiO₂), silicon oxide (SiO₂), silicon nitride (Si₃N₄), aluminum oxide (Al₂O₃), tantalum oxide (Ta₂O₅), strontium titanium oxide (SrTiO₃), zirconium oxide (ZrO₂), hafnium oxide (HfO₂), hafnium silicon oxide (HfSiO₄), lanthanum oxide (La₂O₃), yttrium oxide (Y₂O₃), and lanthanum aluminum oxide (LaAlO₃). The current leakage blocking effect of Mg doping and Mg doping concentration profiles in various dielectric material layers may be shown.

A method of manufacturing a capacitor according to one embodiment of the present invention may include the steps of preparing a first electrode, forming a dielectric layer on the first electrode using an atomic layer deposition (ALD) process, and forming a second electrode on the dielectric layer. The dielectric layer may comprise a doped layer region doped with magnesium (Mg). The dielectric layer may have a non-uniform magnesium (Mg) doping concentration profile along a thickness direction of the dielectric layer between the first electrode and the second electrode.

According to one embodiment, the dielectric layer may comprise a first doped layer region doped with magnesium (Mg) and a second doped layer region doped with magnesium (Mg). The first doped layer region may be disposed in contact with or adjacent to the first electrode. The second doped layer region may be disposed in contact with or adjacent to the second electrode. The second doping layer region may be spaced apart from the first doping layer region.

According to one embodiment, the dielectric layer may comprise an intermediate doping layer region doped with magnesium (Mg) between the first and second doping layer regions. The magnesium (Mg) doping concentration of the intermediate doping layer region may be lower than the magnesium (Mg) doping concentration of each of the first and second doping layer regions. The average magnesium (Mg) doping concentration of the intermediate doping layer region may be lower than the average magnesium (Mg) doping concentration of each of the first and second doping layer regions. In this regard, reference may be made to the capacitor structure of FIG. 1 and a related description at.

According to one embodiment, the dielectric layer may comprise an undoped region between the first and second doped layer regions. The undoped region may be a region that is not doped with magnesium (Mg). In this regard, reference may be made to the capacitor structure of FIG. 2 and the associated description.

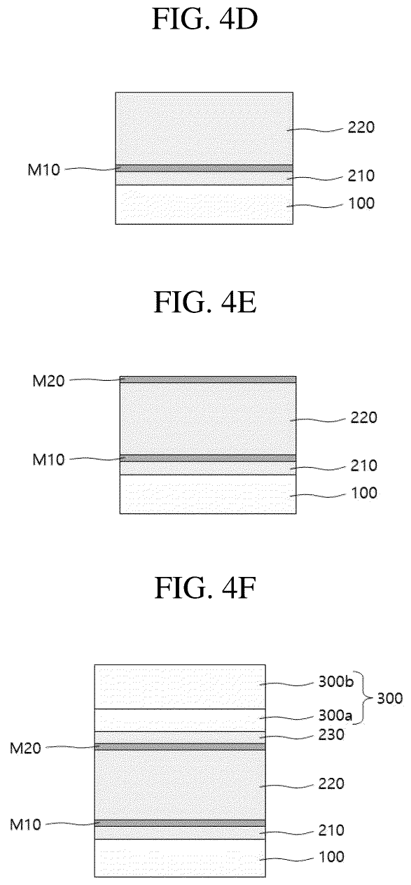

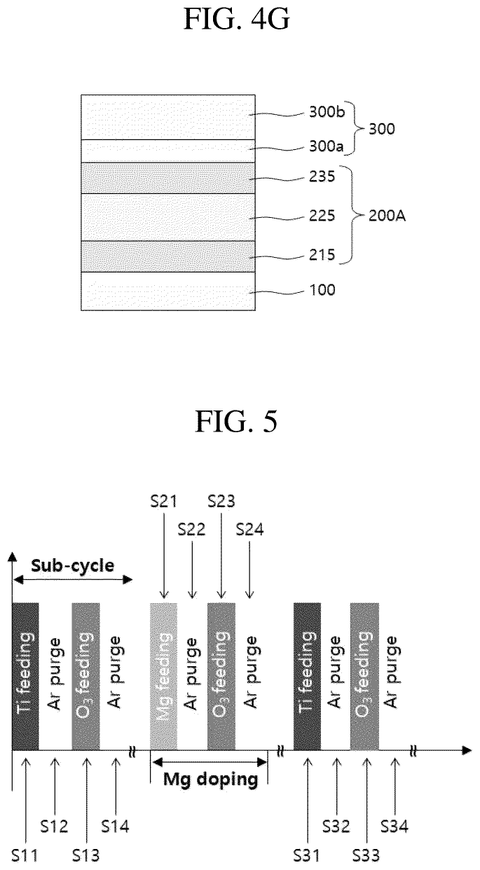

FIGS. 4A through 4G are cross-sectional views illustrating a method of fabricating a capacitor according to one embodiment of the present invention.

Referring to FIG. 4A, a first electrode 100 can be provided. The first electrode 100 may be formed on a predetermined substrate (not shown). The first electrode 100 may comprise, as a non-limiting example, at least one of ruthenium (Ru), ruthenium oxide (RuO₂), iridium (Ir), iridium oxide (IrO₂), molybdenum (Mo), molybdenum oxide (MoO₂), tin (Sn), and tin oxide (SnO₂). For example, the first electrode 100 may be formed by a sputtering process, but the method of forming the first electrode 100 is not limited to a sputtering process and may be varied.

Referring to FIG. 4B a first dielectric layer 210 can be formed on the first electrode 100 by an ALD process. The first dielectric layer 210 may comprise, for example, titanium oxide (TiO₂), silicon oxide (SiO₂), silicon nitride (Si₃N₄), aluminum oxide (Al₂O₃), tantalum oxide (Ta₂O₅), strontium titanium oxide (SrTiO₃), Zirconium oxide (ZrO₂), hafnium oxide (HfO₂), hafnium silicon oxide (HfSiO₄), lanthanum oxide (La₂O₃), yttrium oxide (Y₂O₃), and lanthanum aluminum oxide (LaAlO₃). The materials of the second and third dielectric layers 220 and 230, which will be described below, may also be the same as the first dielectric layer 210. The first dielectric layer 210 may have a thickness of about 5˜30 Å or about 15˜20 Å, as non-limiting examples.

Referring to FIG. 4C, a first magnesium (Mg) doping process may be performed on the first dielectric layer 210 by an ALD process. Through the first magnesium (Mg) doping process, a first doping material layer M10 may be formed on the first dielectric layer 210. The first doping material layer M10 may comprise, for example, MgO.

Referring to FIG. 4D, the second dielectric layer 220 may be formed by an ALD process on the first dielectric layer 210 in which the first magnesium (Mg) doping process was performed. In the process of forming the second dielectric layer 220, or even before, the Mg in the first doping material layer M10 may diffuse, so that the second dielectric layer 220 may be deposited with a crystal structure corresponding to the crystal structure of the first dielectric layer 210.

Referring to FIG. 4E, a second magnesium (Mg) doping process may be performed by an ALD process on the second dielectric layer 220. The second magnesium (Mg) doping process may result in the formation of a second doping material layer M20 on the second dielectric layer 220. The second doping material layer M20 may comprise, for example, MgO.

Referring to FIG. 4F, a third dielectric layer 230 may be formed by an ALD process on the second dielectric layer 220 in which the second magnesium (Mg) doping process was performed. The third dielectric layer 230 may have a thickness of about 5˜30 Å or about 15˜20 Å, as a non-limiting example. During or prior to forming the third dielectric layer 230, the Mg in the second doping material layer M20 may diffuse, so that the third dielectric layer 230 may be deposited with a crystal structure corresponding to the crystal structure of the second dielectric layer 220. The material layer structure from the first dielectric layer 210 to the third dielectric layer 230 may be to constitute one “dielectric layer”.

Next, a second electrode 300 can be formed on the third dielectric layer 230. The second electrode 300 may include a second first electrode 300a and a second electrode 300b. The second first electrode 300a and the second electrode 300b may be stacked (formed) in sequence on the third dielectric layer 230. The second first electrode 300a may include at least one of, for example, ruthenium (Ru), ruthenium oxide (RuO₂), iridium (Ir), iridium oxide (IrO₂, molybdenum (Mo), molybdenum oxide (MoO₂), tin (Sn), and tin oxide (SnO₂). In one example, the material of the second first electrode 300a may be the same as the material of the first electrode 100. The second electrode 300b may include, as a non-limiting example, at least one of platinum (Pt), copper (Cu), molybdenum (Mo), cobalt (Co), palladium (Pd), gold (Au), iridium (Ir), tungsten (W), and nickel (Ni). The second electrode 300b may comprise a metal or alloy, and may have a monolayer structure or a multilayer structure (laminated structure). The second first electrode 300a and the second electrode 300b may be formed, for example, by a sputtering process, but the method of forming them is not limited to a sputtering process and may vary. The formation of the second-2 electrode 300b may be optional.

After the formation of the second electrode 300, post metallization annealing (PMA) can be performed on the resulting material. During the PMA process, the material of the second first electrode 300a may favorably improve the crystallinity of the “dielectric layer” comprising the layers of material from the first dielectric layer 210 to the third dielectric layer 230 (e.g., improve the rutile crystallinity) and obtain a high dielectric rate. Performing PMA with the third dielectric layer 230 disposed below the second first electrode 300a may be more advantageous for improving the crystallinity of the “dielectric layer”. Therefore, it may be preferable to form the second 2-1 electrode 300a after forming the third dielectric layer 230 on the second dielectric layer 220 where the second magnesium (Mg) doping process has been performed. As a non-limiting example, the PMA may be performed at a temperature of about 400° C. in an N₂ (95%)/O₂ (5%) atmosphere for about 30 minutes, but the specific PMA process conditions may be varied.

FIG. 4G shows the structure of the final fabricated capacitor. The structure of FIG. 4G may correspond to the structure of FIG. 1.

Referring to FIG. 4G, the capacitor may include a first electrode 100, a second electrode 300 disposed spaced apart from the first electrode 10), and a dielectric layer 200a disposed between the first electrode 100 and the second electrode 300. The dielectric layer 200a may include a doped layer region doped with magnesium (Mg). The dielectric layer 200a may have a non-uniform magnesium (Mg) doping concentration profile along a thickness direction of the dielectric layer 200a between the first electrode 100 and the second electrode 300. The dielectric layer 200a may include a first doped layer region 215 doped with magnesium (Mg) and a second doped layer region 235 doped with magnesium (Mg). The first doped layer region 215 may be disposed in contact with or adjacent to the first electrode 100. The second doping layer region 235 may be disposed in contact with or adjacent to the second electrode 300. The second doping layer region 235 may be spaced apart from the first doping layer region 215. The dielectric layer 200a may include an intermediate doping layer region 225 doped with magnesium (Mg) between the first and second doping layer regions 215 and 235. The magnesium (Mg) doping concentration of the intermediate doping layer region 225 may be lower than the magnesium (Mg) doping concentration of each of the first and second doping layer regions 215 and 235. The structure of FIG. 4G may correspond to the structure of FIG. 1, and therefore, all of the features described with respect to FIG. 1 may apply to the structure of FIG. 4G.

The first and second doping layer regions 215 and 235 and the intermediate doping layer region 225 may be regions formed by diffusion of Mg into the dielectric layer from the first and second doping material layers M10 and M20 described in FIGS. 4C through 4F. For convenience, Mg is shown in an undiffused state in FIGS. 4C through 4F, but diffusion of Mg may occur during the process of FIGS. 4C through 4F.

FIG. 5 is a graph illustrating a sequence of ALD processes for dielectric layer formation that can be applied to a method of manufacturing a capacitor according to one embodiment of the present invention.

Referring to FIG. 5, the step of forming the first dielectric layer 210 described in FIG. 4b may comprise a step S11 of supplying a precursor for formation of the dielectric layer in a chamber in which the first electrode is disposed, a step S12 of purging the chamber with a first purge gas, a step S13 of supplying a first reactant in the chamber, and a step S14 of purging the chamber with a second purge gas. Here, the precursor for the formation of the dielectric layer may be, for example, a precursor of Ti. The precursor of Ti may be, as a non-limiting example, (CpMe₅)Ti(OMe)₃. The first reactant may be, as a non-limiting example, O₃. The first and second purge gases may be, as a non-limiting example, Ar gas. Steps S11, S12, S13, and S14 may comprise a sub-cycle, and the sub-cycle may be repeated a plurality of times.

The step of performing the first magnesium (Mg) doping process described in FIG. 4C may include the step of supplying a precursor of Mg in the chamber S21, purging the chamber with a third purge gas S22, supplying a second reactant in the chamber S23, and purging the chamber with a fourth purge gas S24. Here, the precursor of Mg may be, as a non-limiting example, Cp₂Mg. The second reactant may be, as a non-limiting example, O₃. The third and fourth purge gases may be, as a non-limiting example, Ar gas. Steps S21, S22, S23, and S24 may be performed in, for example, only one cycle. If the amount of Mg doping is too large, it may have an undesirable effect on the crystallinity of the oil layer. In other words, if the amount of Mg doping is too large, the crystallization of the dielectric layer may be negatively affected. Therefore, it may be desirable to perform only one cycle of steps S21, S22, S23, and S24. However, embodiments of the present invention are not limited to this. Steps S21, S22, S23, and S24 may be referred to as the Mg—O cycle.

The step of forming the second dielectric layer 220 described in FIG. 4D may comprise the steps of supplying a precursor for formation of the dielectric layer in the chamber S31, purging the chamber with a fifth purge gas S32, supplying a third reactant in the chamber S33, and purging the chamber with a sixth purge gas S34. Steps S31, S32, S33, and S34 may be substantially the same as steps S11, S12, S13, and S14, respectively. Steps S31, S32, S33, and S34 may comprise a sub-cycle, and the sub-cycle may be performed a plurality of times.

The steps of performing the second magnesium (Mg) doping process described in FIG. 4E may be substantially the same as the steps of performing the first magnesium (Mg) doping process. The steps of performing the second magnesium (Mg) doping process may include the same steps as steps S21, S22, S23, and S24.

The steps of forming the third dielectric layer 230 described in FIG. 4F may be substantially the same as the steps of forming the first dielectric layer 210. The step of forming the third oil layer 230 may include the same steps as steps S11, S12, S13, and S14.

In a comparative example, when Al doping is performed instead of Mg doping, a precursor of Al may be used instead of a precursor of Mg. The precursor of Al may be, for example, trimethyl aluminum (TMA).

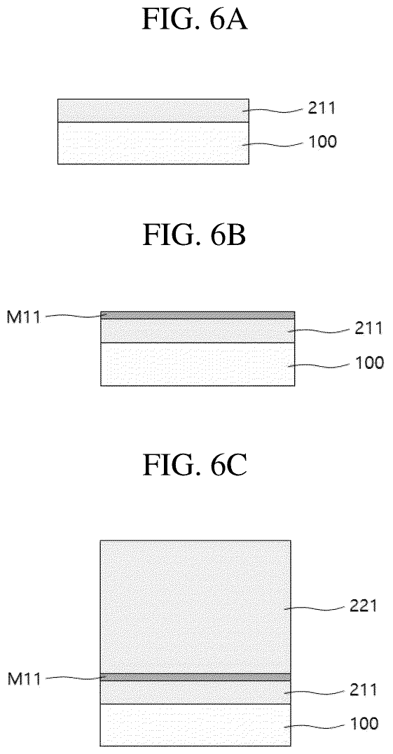

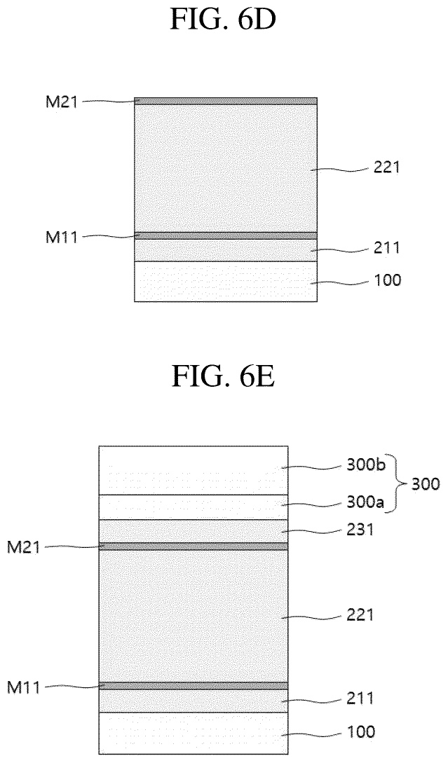

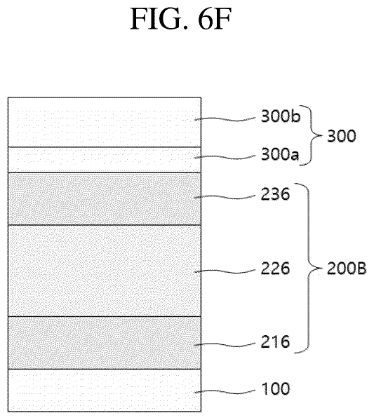

FIGS. 6A through 6F are cross-sectional views illustrating a method of fabricating a capacitor according to another embodiment of the present invention.

Referring to FIG. 6A, a first electrode 100 can be prepared. Then, a first dielectric layer 211 can be formed on the first electrode 100 by an ALD process. The first dielectric layer 211 may comprise, for example, titanium oxide (TiO₂), silicon oxide (SiO₂), silicon nitride (Si₃N₄), aluminum oxide (Al₂O₃), tantalum oxide (Ta₂O₅), strontium titanium oxide (SrTiO₃), zirconium oxide (ZrO₂), hafnium oxide (HfO₂), hafnium silicon oxide (HfSiO₄), lanthanum oxide (La₂O₃), yttrium oxide (Y₂O₃), and lanthanum aluminum oxide (LaAlO₃). The materials of the second and third dielectric layers 221 and 231, which will be described below, may also be the same as the first dielectric layer 211. The first dielectric layer 211 may have a thickness of about 5˜30 Å or about 15˜20 Å, as non-limiting examples.

Referring to FIG. 6B, a first magnesium (Mg) doping process may be performed on the first dielectric layer 211 by an ALD process. The first magnesium (Mg) doping process may result in the formation of a first doped material layer M11 on the first dielectric layer 211. The first doping material layer M11 may comprise, for example, MgO.

Referring to FIG. 6C, the second dielectric layer 221 may be formed by an ALD process on the first dielectric layer 211 in which the first magnesium (Mg) doping process was performed. During or prior to forming the second dielectric layer 221, the Mg in the first doping material layer M11 may diffuse, so that the second dielectric layer 221 may be deposited with a crystal structure corresponding to the crystal structure of the first dielectric layer 211. The thickness of the second dielectric layer 221 may be thicker than the thickness of the second dielectric layer 220 of FIG. 4D.

Referring to FIG. 6D, a second magnesium (Mg) doping process may be performed by an ALD process on the second dielectric layer 221. The second magnesium (Mg) doping process may result in the formation of a second doping material layer M21 on the second dielectric layer 221. The second doping material layer M21 may comprise, for example, MgO.

Referring to FIG. 6E, a third dielectric layer 231 may be formed by an ALD process on the second dielectric layer 221 where the second magnesium (Mg) doping process was performed. The third dielectric layer 231 may have a thickness of about 5˜30 Å or about 15˜20 Å, as a non-limiting example. During or prior to forming the third dielectric layer 231, the Mg in the second doping material layer M21 may diffuse, so that the third dielectric layer 231 may be deposited with a crystal structure corresponding to the crystal structure of the second dielectric layer 221. The material layer structure from the first dielectric layer 211 to the third dielectric layer 231 can be to constitute a single “dielectric layer”.

Next, a second electrode 300 can be formed on the third dielectric layer 231. The second electrode 300 may include a second first electrode 300a and a second electrode 300b. The second electrode 300b may be omitted.

After the formation of the second electrode 300, post metallization annealing (PMA) can be performed on the resulting material. During the PMA process, the material of the second first electrode 300a may favorably improve the crystallinity of the “dielectric layer” comprising the layers of material from the first dielectric layer 211 to the third dielectric layer 231 (e.g., improve the rutile crystallinity) and obtain a high dielectric constant.

FIG. 6F shows the structure of the final fabricated capacitor. The structure of FIG. 6f may correspond to the structure of FIG. 2.

Referring to FIG. 6F, the capacitor may include a first electrode 100, a second electrode 300 disposed spaced apart from the first electrode 100, and a dielectric layer 200B disposed between the first electrode 100 and the second electrode 300. The dielectric layer 200B may include a doped layer region doped with magnesium (Mg). The dielectric layer 200B may have a non-uniform magnesium (Mg) doping concentration profile along a thickness direction of the dielectric layer 200B between the first electrode 100 and the second electrode 300. Dielectric layer 200B may include a magnesium (Mg) doped first doped layer region 216 and a magnesium (Mg) doped second doped layer region 236. The first doping layer region 216 may be disposed in contact with or adjacent to the first electrode 100. The second doping layer region 236 may be disposed in contact with or adjacent to the second electrode 300. The second doping layer region 236 may be spaced apart from the first doping layer region 216. The dielectric layer 200B may include an undoped region 226 that is not doped with magnesium (Mg) between the first and second doped layer regions 216 and 236. The structure of FIG. 6F may correspond to the structure of FIG. 2, and thus all of the features described with respect to FIG. 2 may apply to the structure of FIG. 6F.

The first and second doping layer regions 216 and 236 may be regions formed by diffusion of Mg into the dielectric layer from the first and second doping material layers M11 and M21 described in FIGS. 6B through Ee. For convenience, Mg is shown undiffused in FIGS. 6B through 6E, but diffusion of Mg may occur during the process of FIGS. 6B through 6E.

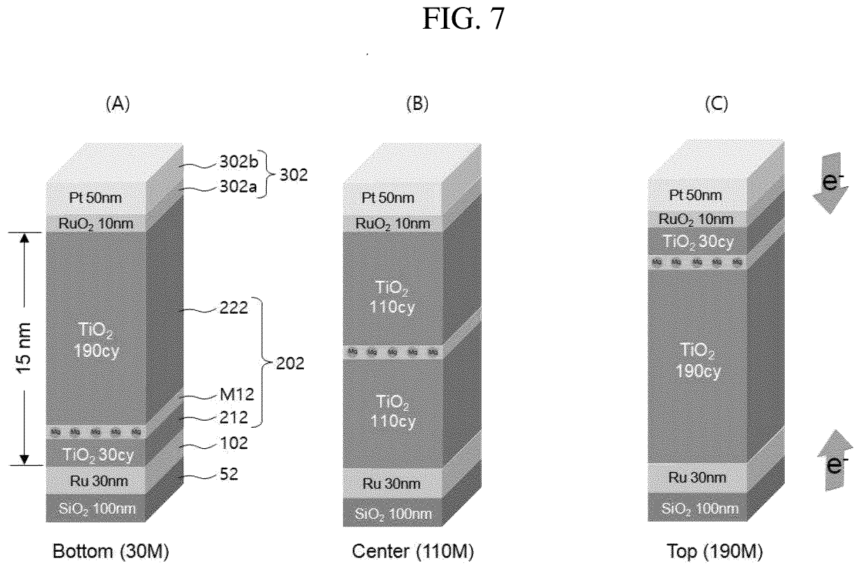

FIG. 7 is a drawing to illustrate a method for fabricating a capacitor device (sample) for obtaining experimental data.

(A), (B), and (C) of FIG. 7 are schematic diagrams of a bottom, center, and top sample, respectively, where the Mg—O cycles for doping are inserted at 30, 110, and 190 cycles from the bottom, out of a total of 220 TiO₂ deposition cycles. For the bottom sample, the Mg-doped doped layer region may be placed in the lower portion of the dielectric layer 202 (i.e., the bottom region) by diffusion. For a center sample, the Mg-doped doped layer region may be disposed in the central portion of the dielectric layer 202 (i.e., the center region). For a top sample, the Mg-doped doped layer region may be disposed in the upper portion (i.e., top region) of the dielectric layer 202 by diffusion.

In FIG. 7, reference numeral 52 refers to an underlayer, 102 refers to a first electrode, 202 refers to a dielectric layer, and 302 refers to a second electrode. Reference numeral 212 denotes a first dielectric layer, M12 denotes a doping material layer, and 222 denotes a second dielectric layer. Reference numeral 302a denotes the second first electrode, and reference numeral 302b denotes the second electrode. In FIG. 7, only one doping material layer M12 is formed within the dielectric layer 202.

On the right side of FIG. 7, an electron inflow path is shown by an arrow. In the case of a negative voltage application condition, where a relatively low voltage (negative voltage) is applied to the second electrode 302 of the first electrode 102 and the second electrode 302, electrons may flow from the second electrode 302 into the dielectric layer 202. In the case of a positive voltage application condition, where a higher voltage (positive voltage) is applied to the second electrode 302 relative to the first electrode 102 and the second electrode 302, electrons may flow into the dielectric layer 202 from the first electrode 102.

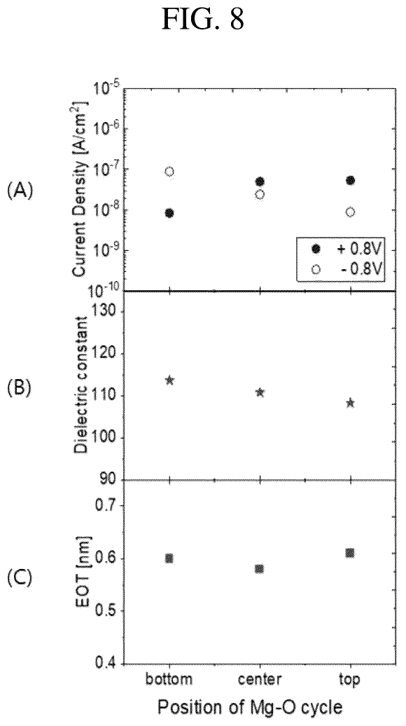

FIG. 8 is a graph showing the results of measuring/evaluating the current leakage characteristics, dielectric constant, and equivalent oxide thickness (EOT) as a function of the position of the Mg—O cycle (i.e., doping position) of the capacitor element (sample) of FIG. 7. (A) Graph shows the current leakage characteristics, (B) Graph shows the dielectric constant, and (C) Graph shows the equivalent oxide thickness (EOT).

Referring to graph (A) in FIG. 8, the current density can be seen when a positive voltage (+0.8 V) is applied to the capacitor element and when a negative voltage (−0.8 V) is applied. In the positive voltage case, a voltage of 0V is applied to the first electrode and a voltage of +0.8V is applied to the second electrode. The negative voltage is applied when a voltage of 0V is applied to the first electrode and a voltage of −0.8V is applied to the second electrode. The bottom sample showed a relatively low current density under the positive voltage application condition. This may mean that the Mg doped layer regions placed in the bottom region of the dielectric layer or adjacent to it exhibit a good electron blocking effect under positive voltage application. For the top sample, the current density was relatively low under the negative voltage application condition. This may mean that the Mg doped layer regions arranged in the top region or adjacent regions of the dielectric layer exhibit good electron blocking effect under negative voltage application.

According to an embodiment of the present invention, as described with reference to FIGS. 1 and 2 and the like, a first doped layer region can be disposed in a bottom region of an oil field or an area adjacent thereto, and a second doped layer region can be disposed in a top region of the oil field or an area adjacent thereto. In this case, the leakage current characteristics can be improved under both positive voltage application conditions and negative voltage application conditions. In other words, the effect of improving the leakage current characteristics of the dielectric layer in both directions can be obtained.

On the other hand, referring to the (B) and (C) graphs of FIG. 8, the variation of the dielectric constant and the variation of the equivalent oxide thickness (EOT) with the position of the Mg—O cycle (i.e., doping position) may not be significant or trending.

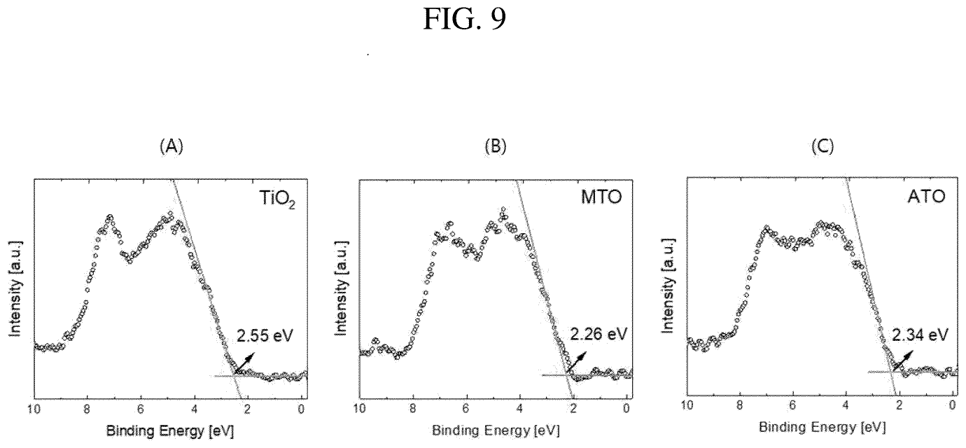

FIG. 9 is a graph showing the results of an X-ray photoelectron spectroscopy (XPS) analysis of dielectric layers prepared in accordance with embodiments and comparative examples of the present invention. FIG. 9 includes valence band edge information from XPS. From the valence band edge information, the energy barrier of the dielectric layer can be determined. FIG. 9 (A) shows the results for an undoped TiO₂ layer. (B) in FIG. 9 is the result for a TiO₂ layer (labeled MTO) containing first and second doped layer regions doped with Mg. The dielectric layer corresponding to (B) of FIG. 9 may correspond to the dielectric layer (D10) of FIG. 1. (C) of FIG. 9 is a result for a TiO₂ layer (labeled ATO) comprising first and second doped layer regions doped with Al. The dielectric layer corresponding to (C) of FIG. 9 may have a structure similar to the dielectric layer D10 of FIG. 1, but the first and second doped layer regions may be regions doped with Al rather than Mg. (B) of FIG. 9 corresponds to an embodiment, and (A) and (C) correspond to comparative examples.

Referring to FIG. 9, it can be seen that the energy barrier is increased by about 0.29 eV for MTO and 0.21 eV for ATO compared to undoped TiO₂. TiO₂ is known to have a relatively large current leakage compared to its low bandgap (3.1 eV), which can be attributed to the n-type character of TiO₂, in which the Fermi level is pushed closer to the conduction band by the inherent Ti interstitial, oxygen vacancy. Therefore, when a material with a low number of valence atoms is doped to displace Ti, it can create an energy level inside the bandgap that can trap electrons, which can lower the Fermi level of the entire dielectric layer and raise the energy barrier for electron conduction. The energy barrier raising effect can be more effective in the doping of +2 dopant materials because the energy level created by the substitution of +4 Ti by a +2 divalent dopant (i.e., Mg) can hold (i.e., trap) one additional electron compared to the energy level created by the substitution of a +3 divalent dopant (e.g., Al). Therefore, the leakage current blocking effect can be further improved by doping with magnesium (Mg).

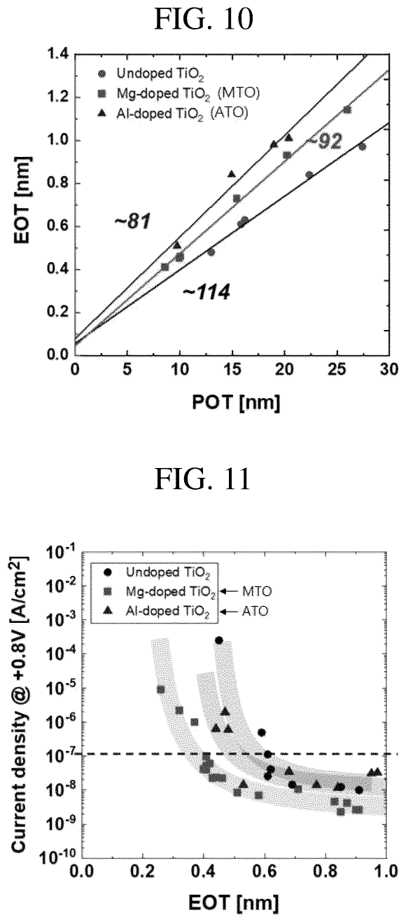

FIG. 10 is a graph showing the results of evaluating the dielectric constants of dielectric layers according to the embodiments and comparative examples described in FIG. 9. The Mg-doped TiO2 in FIG. 10 may be the MTO described in FIG. 9, and the Al-doped TiO2 may be the ATO described in FIG. 9. In FIG. 10, POT denotes the physical oxide thickness and EOT denotes the equivalent oxide thickness.

Referring to FIG. 10, it can be seen that the MTO prepared according to an embodiment has a dielectric constant somewhat lower than undoped TiO2, but higher than the ATO according to a comparative example.

FIG. 11 is a graph showing the results of evaluating the electrical characteristics of a capacitor with a dielectric layer according to the embodiments and comparative examples described in FIG. 9. The Mg-doped TiO₂ in FIG. 11 may be the MTO described in FIG. 9, and the Al-doped TiO₂ may be the ATO described in FIG. 9.

Referring to FIG. 11, a capacitor with MTO according to an embodiment may exhibit lower leakage current characteristics compared to a capacitor with ATO or undoped TiO₂ according to a comparative example. As a result, it may be possible to fabricate a capacitor with a smaller EOT according to an embodiment.

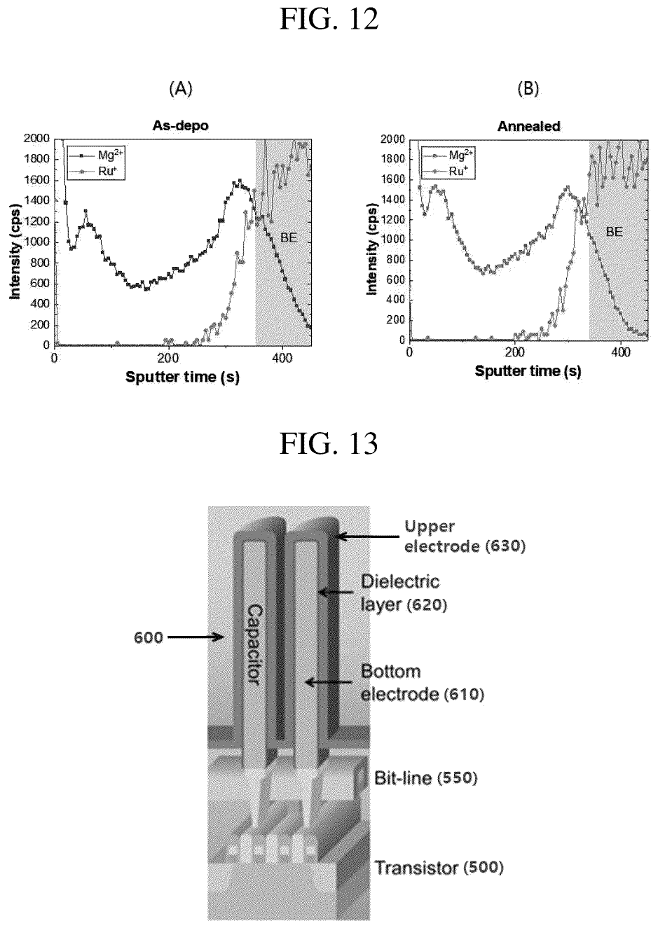

FIG. 12 is a graph showing the results of time-of-flight secondary ion mass spectrometry (ToF-SIMS) measurements of magnesium (Mg) doping concentration profiles in the dielectric layer that can be obtained in a method of manufacturing a capacitor according to one embodiment of the present invention. In FIG. 12, graph (A) was measured before deposition of the dielectric layer and subsequent annealing, and graph (B) was measured after deposition of the dielectric layer and subsequent annealing. In FIG. 12, BE represents a first electrode. The physical thickness of the dielectric layer may be on the order of 10 nm.

Referring to FIG. 12, a dielectric layer prepared according to an embodiment may have a first doped layer region doped with Mg in a region in contact with to or adjacent to a first electrode, and may include a second doped layer region doped with Mg in a region in contact with to or adjacent to a second electrode on top. Further, the dielectric layer may include an intermediate doped layer region having a relatively low doping concentration between the first doped layer region and the second doped layer region. The dielectric layer may have a doping profile similar to the dielectric layer (D10) described in FIG. 1. However, the results for the top surface side of the dielectric layer in FIG. 12 may include some measurement errors.

The capacitor structure manufactured according to an embodiment of the present invention, i.e., the capacitor structure described in FIGS. 1 to 3, can be applied to various electronic/semiconductor devices. For example, a capacitor according to an embodiment of the present invention may be applied to a memory device that utilizes a capacitor as a data storage member. Here, the memory device may be a dynamic random access memory (DRAM). In order to apply the capacitor to DRAM, it may be desirable to manufacture the capacitor by an ALD process. Since the capacitors according to embodiments of the present invention can be fabricated using an ALD process, they can be easily adapted to DRAMs. FIGS. 1 to 3 illustrate a capacitor with a simple planar structure, but when applied as a capacitor for a DRAM, the capacitor according to an embodiment of the present invention can have various modified structures, such as a cylinder shape, a cup shape, and the like.

FIG. 13 is a diagram illustrating an exemplary configuration of a DRAM device to which a capacitor may be applied according to one embodiment of the present invention.

Referring to FIG. 13, a DRAM may include a cell transistor 500 and a capacitor 600 electrically coupled thereto. The capacitor 600 may include a first electrode 610 and a second electrode 630 and a dielectric layer 620 disposed therebetween. The first electrode 610 may be a lower electrode, and the second electrode 630 may be a higher electrode. The dielectric layer 620 may include a doped layer region doped with magnesium (Mg). The dielectric layer 620 may have a non-uniform magnesium (Mg) doping concentration profile along a thickness direction of the dielectric layer 620 between the first electrode 610 and the second electrode 630. Additionally, the dielectric layer 620 can have any of the characteristics of the aforementioned embodiments. However, the structure of the capacitor 600 shown in FIG. 13 is exemplary only and can be varied. The capacitor according to embodiments of the present invention can be applied to any capacitor structure used in conventional DRAMs. When the capacitor according to an embodiment of the present invention is applied to a DRAM, it can be advantageous in improving integration and improving performance. Furthermore, the capacitor according to an embodiment of the present invention can be applied to other memory devices or other electronic/semiconductor devices other than DRAM. In FIG. 13, undescribed reference numeral 550 indicates a bitline.

A method of fabricating an electronic device (e.g., a memory device) according to embodiments of the present disclosure may include a method of fabricating a capacitor according to any of the foregoing embodiments.

According to embodiments of the present invention described above, it is possible to implement a capacitor comprising a dielectric layer that can have a thin equivalent oxide thickness (EOT), having a high permittivity, but with improved leakage current characteristics. According to one embodiment, the dielectric layer may include doped layer regions doped with magnesium (Mg) and may have a non-uniform magnesium (Mg) doping concentration profile along the thickness direction of the dielectric layer. For example, the dielectric layer may include a first doped layer region in contact with or adjacent to a first electrode and a second doped layer region in contact with or adjacent to a second electrode. In this case, the effect of significantly improving the leakage current characteristics of the dielectric layer in both directions can be obtained. Furthermore, the leakage current blocking effect can be further improved by the properties of the divalent element magnesium (Mg), and as a result, a smaller equivalent oxide film thickness (EOT) can be obtained. The capacitors according to embodiments of the present invention can be usefully applied to electronic devices, for example, memory devices such as DRAMs, which can be advantageous for improving the integration and performance of memory devices.

While the present disclosure has been described with reference to the embodiments illustrated in the figures, the embodiments are merely examples, and it will be understood by those skilled in the art that various changes in form and other embodiments equivalent thereto can be performed. Therefore, the technical scope of the disclosure is defined by the technical idea of the appended claims.

The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A capacitor comprising:
a first electrode;
a second electrode disposed spaced apart from the first electrode; and
a dielectric layer disposed between the first electrode and the second electrode,
wherein the dielectric layer comprises a doped layer region doped with magnesium (Mg),
wherein the dielectric layer has a non-uniform magnesium (Mg) doping concentration profile along a thickness direction of the dielectric layer between the first electrode and the second electrode.

2. The capacitor of claim 1, wherein the dielectric layer comprising:
a first doped layer region doped with magnesium (Mg), which is in contact with or adjacent to the first electrode; and
a second doped layer region doped with magnesium (Mg) which is in contact with or adjacent to the second electrode and spaced apart from the first doped layer region.

3. The capacitor of claim 2,
wherein the dielectric layer comprises an intermediate doped layer region doped with magnesium (Mg) between the first and second doped layer regions,
wherein a magnesium (Mg) doping concentration of the intermediate doping layer region is lower than a magnesium (Mg) doping concentration of each of the first and second doping layer regions.

4. The capacitor of claim 2, wherein the dielectric layer comprises an undoped region between the first and second doped layer regions.

5. The capacitor of claim 1, wherein the dielectric layer comprises at least one of selected from the group consisting of titanium oxide, silicon oxide, silicon nitride, aluminum oxide, tantalum oxide, strontium titanium oxide, zirconium oxide, hafnium oxide, hafnium silicon oxide, lanthanum oxide, yttrium oxide, and lanthanum aluminum oxide.

6. I The capacitor of claim 5, wherein the dielectric layer comprises titanium oxide.

7. The capacitor of claim 1, wherein the dielectric layer has a rutile crystalline phase.

8. The capacitor of claim 1, wherein the first electrode comprises at least one of selected from the group consisting of ruthenium, ruthenium oxide, iridium, iridium oxide, molybdenum, molybdenum oxide, tin, and tin oxide.

9. The capacitor of claim 1, wherein the second electrode comprises at least one of selected from the group consisting of: ruthenium, ruthenium oxide, iridium, iridium oxide, molybdenum, molybdenum oxide, tin, and tin oxide.

10. A memory device comprising the capacitor of any one of claim 1 as a data storage member.

11. The memory device of claim 10, wherein the memory device comprises a dynamic random access memory (DRAM).

12. A method of manufacturing a capacitor, comprising:
prepare a first electrode;
forming a dielectric layer on the first electrode using an atomic layer deposition (ALD) process; and
forming a second electrode on the dielectric layer,
wherein the dielectric layer comprises a doped layer region doped with magnesium (Mg),
wherein the dielectric layer has a non-uniform magnesium (Mg) doping concentration profile along a thickness direction of the dielectric layer between the first electrode and the second electrode.

13. The method of claim 12, wherein the dielectric layer comprising:
a first doped layer region doped with magnesium (Mg), which is in contact with or adjacent to the first electrode; and
a second doped layer region doped with magnesium (Mg), which is in contact with or adjacent to the second electrode and spaced apart from the first doped region.

14. The method of claim 13,
wherein the dielectric layer comprises an intermediate doped layer region doped with magnesium (Mg) between the first and second doped layer regions,
wherein a magnesium (Mg) doping concentration of the intermediate doping layer region is lower than a magnesium (Mg) doping concentration of each of the first and second doping layer regions.

15. The method of claim 13, wherein the dielectric layer comprises an undoped region between the first and second doped layer regions.

16. The method of claim 12, wherein forming the dielectric layer comprising:
forming a first dielectric layer on the first electrode using an ALD process;
performing a first magnesium (Mg) doping process on the first dielectric layer using an ALD process;
forming a second dielectric layer on the first dielectric layer in which the first magnesium (Mg) doping process has been performed using an ALD process;
performing a second magnesium (Mg) doping process on the second dielectric layer using an ALD process; and
forming a third dielectric layer on the second dielectric layer in which the second magnesium (Mg) doping process has been performed using an ALD process.

17. The method of claim 16, wherein the step of forming the first dielectric layer comprising:
supplying a precursor for a formation of the dielectric layer in a chamber in which the first electrode is disposed;
purging the chamber with a first purge gas;
supplying a first reactant into the chamber; and
purging the chamber with a second purge gas,
wherein the step of performing the first magnesium (Mg) doping process comprising:
supplying a precursor of Mg into the chamber;
purging the chamber with a third purge gas;
supplying a second reactant into the chamber; and
purging the chamber with a fourth purge gas.

18. The method of claim 12, wherein the dielectric layer comprises at least one of selected from the group consisting of titanium oxide, silicon oxide, silicon nitride, aluminum oxide, tantalum oxide, strontium titanium oxide, zirconium oxide, hafnium oxide, hafnium silicon oxide, lanthanum oxide, yttrium oxide, and lanthanum aluminum oxide.

19. The method of claim 18, wherein the dielectric layer comprises titanium oxide.

20. The method of claim 12, wherein the dielectric layer has a rutile crystalline phase.

21. The method of claim 12, wherein at least one of the first and second electrodes comprises at least one of selected from the group consisting of ruthenium, ruthenium oxide, iridium, iridium oxide, molybdenum, molybdenum oxide, tin, and tin oxide.
